(19) United States
(12) Patent Application Publication
(10) Pub. No.: US 2012/0168757 A1
(43) Pub. Date: Jul. 5, 2012

(54) Transistors, Methods Of Manufacturing The Same And Electronic Devices Including Transistors

(75) Inventors: Kyung-bae Park, Seoul (KR); Myung-kwan Ryu, Yongin-si (KR); Kwang-hee Lee, Suwon-si (KR); Tae-sang Kim, Seoul (KR); Eok-su Kim, Seongnam-si (KR); Kyoung-seok Son, Seoul (KR); Hyun-suk Kim, Hwaseong-si (KR); Wan-joo Maeng, Yongin-si (KR); Joon-seok Park, Seongnam-si, Gyeonggi-do (KR)

(73) Assignee: SAMSUNG ELECTRONICS CO., LTD., Suwon-si (KR)

(21) Appl. No.: 13/165,301

(22) Filed: Jun. 21, 2011

(30) Foreign Application Priority Data
Dec. 29, 2010 (KR) 10-2010-0138042

(51) Int. Cl. H01L 29/786; H01L 21/336

(52) U.S. Cl. 257/59; 438/156; 257/E29.273; 257/E21.412

(57) ABSTRACT

A transistor includes a channel layer disposed above a gate and including an oxide semiconductor. A source electrode contacts a first end portion of the channel layer, and a drain electrode contacts a second end portion of the channel layer. The channel layer further includes a fluorine-containing region formed in an upper portion of the channel layer between the source electrode and the drain electrode.

### CROSS-REFERENCE TO RELATED APPLICATION(S)

This application claims priority under 35 U.S.C. §119 to Korean Patent Application No. 10-2010-0138042, filed on Dec. 29, 2010, in the Korean Intellectual Property Office, the entire contents of which is incorporated herein by reference.

### BACKGROUND

1. Field

Example embodiments relate to transistors, methods of manufacturing transistors, and electronic devices including transistors.

2. Description of the Related Art

Transistors are used as switching devices and/or driving devices in electronic devices. Because thin film transistors (TFTs) may be manufactured on glass substrates or plastic substrates, TFTs are used in flat panel display devices such as liquid crystal display (LCD) devices, organic light-emitting display (OLED) devices, and the like.

Using an oxide layer having a relatively high carrier mobility as a channel layer may improve operating characteristics of a transistor. However, conventional oxide layers are relatively sensitive to their environment (e.g., light and the like), and thus, characteristics of the transistors may change relatively easily.

### SUMMARY

Example embodiments provide transistors of which characteristic variations due to environmental conditions such as light are suppressed and/or which have improved performance. Example embodiments also provide methods of manufacturing transistors and electronic devices including transistors.

Additional aspects will be set forth in part in the description which follows and, in part, will be apparent from the description, or may be learned by practice of example embodiments.

According to at least one example embodiment, a transistor includes: a gate; a channel layer disposed above the gate and including an oxide semiconductor; a source electrode contacting a first end portion of the channel layer; and a drain electrode contacting a second end portion of the channel layer. The channel layer includes a fluorine-containing region formed in an upper portion of the channel layer between the source electrode and the drain electrode.

According to at least some example embodiments, the fluorine-containing region may be formed in a back channel region of the channel layer. The source electrode may be formed on a sidewall and an upper surface of the first end portion of the channel layer, and the drain electrode may be formed on a sidewall and an upper surface of the second end portion of the channel layer.

According to at least some example embodiments, only the upper portion of the channel layer between the source electrode and the drain electrode may be a fluorine-containing region.

According to at least some example embodiments, an interface region between the channel layer and at least one of the source electrode and the drain electrode may be a non-fluorine-containing region. Alternatively, an interface region between the channel layer and the source electrode and an interface region between the channel layer and the drain electrode may be non-fluorine-containing regions.

The fluorine-containing region may be a region treated with plasma including fluorine. The fluorine-containing region may have a thickness of between about 1 nm and about 40 nm, inclusive. The oxide semiconductor may be a ZnO-based oxide semiconductor including at least one of: hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

According to at least one other example embodiment, a flat panel display device includes a transistor. The transistor includes: a gate; a channel layer disposed above the gate and including an oxide semiconductor; a source electrode contacting a first end portion of the channel layer; and a drain electrode contacting a second end portion of the channel layer. The channel layer includes a fluorine-containing region formed in an upper portion of the channel layer between the source electrode and the drain electrode. The flat panel display device may be a liquid crystal display (LCD) device, an organic light emitting display (OLED) device or the like. The transistor may be used as a switching device and/or a driving device in the flat panel display device.

According to at least one other example embodiment, a transistor includes: a channel layer including an oxide semiconductor and a fluorine-containing region formed in a lower portion of the channel layer; a source electrode contacting a first end portion of the channel layer; and a drain electrode contacting a second end portion of the channel layer.

According to at least some example embodiments, the channel layer may have a multi-layer structure. The fluorine-containing region may be formed across an entire width of the lower portion of the channel layer.

According to at least some example embodiments, the source electrode may cover the upper surface of the first end portion of the channel layer, and the drain electrode may cover the upper surface of the second end portion of the channel layer.

The fluorine-containing region may be a region treated with plasma including fluorine. The fluorine-containing region may have a thickness between about 1 nm and about 40 nm, inclusive.

The oxide semiconductor may be a ZnO-based oxide semiconductor including at least one of: hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

According to at least one other example embodiment, a flat panel display device includes a transistor. The transistor includes: a channel layer including an oxide semiconductor and a fluorine-containing region formed in a lower portion of the channel layer; a source electrode contacting a first end portion of the channel layer; and a drain electrode contacting a second end portion of the channel layer. The flat panel display device may be a liquid crystal display device, an organic light emitting display device, or the like. The transistor may be used as a switching device and/or a driving device in the flat panel display device.

According to at least one other example embodiment, a method of manufacturing a transistor includes: forming a gate; forming a gate insulating layer to cover the gate; forming a channel layer on the gate insulating layer, the channel layer including an oxide semiconductor; forming a source electrode and a drain electrode, the source electrode contacting a first end portion of the channel layer, and the drain electrode contacting a second end portion of the channel layer; and forming a fluorine-containing region in an upper portion of the channel layer between the source electrode and the drain electrode.

According to at least some example embodiments, the forming of the fluorine-containing region may include: treating the upper portion of the channel layer between the source electrode and the drain electrode with plasma including fluorine. The treating of the upper portion may be performed using a source gas including at least one of: F₂, NF₃, SF₆, CF₄, C₂F₆, CHF₃, CH₃F, and CH₂F₂. The treating of the upper portion may be performed using one of reactive ion etching (RIE) equipment, plasma-enhanced chemical vapor deposition (PECVD) equipment, and inductively coupled plasma-chemical vapor deposition (ICP-CVD) equipment.

The fluorine-containing region may be formed to have a thickness of between about 1 nm and about 40 nm, inclusive.

The oxide semiconductor may be a ZnO-based oxide semiconductor including at least one of: hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

According to at least one other example embodiment, a method of manufacturing a transistor includes: forming a channel layer including an oxide semiconductor and having a fluorine-containing region in a lower portion of the channel layer; forming a source electrode and a drain electrode, the source electrode contacting a first end portion of the channel layer and the drain electrode contacting a second end portion of the channel layer; forming a gate insulating layer to cover the channel layer, the source electrode, and the drain electrode; and forming a gate on the gate insulating layer.

According to at least some example embodiments, the forming of the channel layer may include: forming a first channel material layer; treating the first channel material layer with plasma including fluorine; and forming a second channel material layer on the first channel material layer.

The treating of the first channel material layer may be performed using a source gas including at least one of: F₂, NF₃, SF₆, CF₄, C₂F₆, CHF₃, CH₃F, and CH₂F₂. The plasma treating may be performed using one of reactive ion etching (RIE) equipment, plasma-enhanced chemical vapor deposition (PECVD) equipment, and inductively coupled plasma-chemical vapor deposition (ICP-CVD) equipment.

The fluorine-containing region may have a thickness of between about 1 nm and about 40 nm, inclusive. The oxide semiconductor may be a ZnO-based oxide semiconductor including at least one of: hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

### BRIEF DESCRIPTION OF THE DRAWINGS

These and/or other aspects will become apparent and more readily appreciated from the following description of example embodiments, taken in conjunction with the accompanying drawings in which:

FIG. 1 is a cross-sectional view of a transistor according to an example embodiment;

FIG. 2 is a cross-sectional view of a transistor according to another example embodiment;

FIGS. 3A through 3D are cross-sectional views illustrating a method of manufacturing a transistor according to an example embodiment;

FIGS. 4A through 4F are cross-sectional views illustrating a method of manufacturing a transistor according to another example embodiment;

FIG. 5 is a graph of drain current I_{DS} versus gate voltage V_{GS} showing example variations in characteristics in response to irradiated light for a transistor according to a comparative example; and

FIG. 6 is a graph of drain current I_{DS} versus gate voltage V_{GS} showing, example variations in characteristics in response to irradiated light for a transistor according to an example embodiment.

### DETAILED DESCRIPTION

Various example embodiments will now be described more fully with reference to the accompanying drawings in which some example embodiments are shown.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Reference will now be made in detail to embodiments, examples of which are illustrated in the accompanying drawings, wherein like reference numerals refer to the like elements throughout. In this regard, example embodiments may have different forms and should not be construed as being limited to the descriptions set forth herein. Accordingly, the example embodiments are merely described below, by referring to the figures, to explain aspects of the present description.

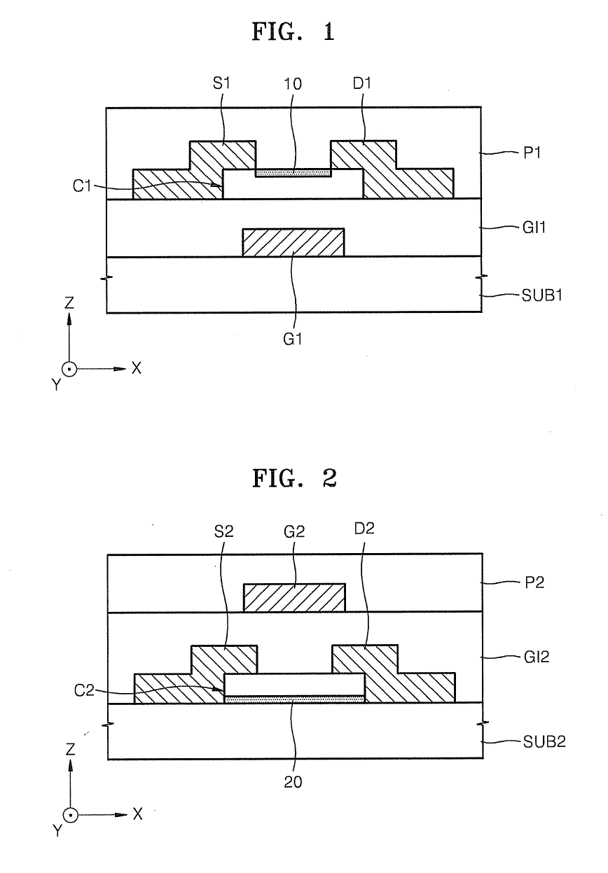

FIG. 1 is a cross-sectional view of a transistor according to an example embodiment. The transistor shown in FIG. 1 is a thin film transistor (TFT) having a bottom gate structure in which a gate G1 is disposed below a channel layer C1.

Referring to the TFT shown in FIG. 1, the gate G1 is disposed on a substrate SUB1. The substrate SUB1 may be a glass substrate, a plastic substrate, a silicon substrate, or any substrate used in conventional semiconductor devices. The gate G1 may be formed of an electrode material such as a metal, a conductive oxide, or the like.

A gate insulating layer GI1 is disposed on the substrate SUB1 to cover the gate G1. The gate insulating layer GI1 may be a silicon oxide layer, a silicon oxynitride layer, a silicon nitride layer, or another material layer such as a high-k dielectric material layer having a dielectric constant higher than the silicon nitride layer. The gate insulating layer GI1 may have a single layer structure or a multi-layer structure including at least two layers selected from a group including the silicon oxide layer, the silicon oxynitride layer, the silicon nitride layer, and the high-k dielectric material layer. When the gate insulating layer GI1 has a multi-layer structure, the gate insulating layer GI1 may include, for example, the silicon nitride layer and the silicon oxide layer stacked sequentially on the substrate SUB1 and the gate G1.

Still referring to FIG. 1, the channel layer C1 is disposed on the gate insulating layer GI1 above the gate G1. As shown in FIG. 1, the width of the channel layer C1 in the X-axis direction is greater than the width of the gate G1 in the X-axis direction. However, in alternative example embodiments, the width of the channel layer C1 may be less than or equal to the width of the gate G1. The channel layer C1 may include an oxide semiconductor such as a ZnO-based oxide semiconductor. When the channel layer C1 includes the ZnO-based oxide semiconductor, the ZnO-based oxide semiconductor may include at least one selected from the group including: a transition metal such as hafnium (Hf), yttrium (Y), tantalum (Ta), zirconium (Zr), titanium (Ti), copper (Cu), nickel (Ni), or chromium (Cr), a Group III element such as indium (In), gallium (Ga), or aluminum (Al), a Group IV element such as tin (Sn), a Group II element such as magnesium (Mg), and/or other elements. In a more specific example, the channel layer C1 may include an oxide semiconductor such as: hafnium-indium-zinc-oxide (HfInZnO), gallium-indium-zinc-oxide (GaInZnO), yttrium-indium-zinc-oxide (YInZnO), tantalum-indium-zinc-oxide (TaInZnO), or the like. The oxide semiconductor used to form the channel layer C1 may be amorphous, crystalline, or a mixture of amorphous and crystalline. A material for the channel layer C1 is not limited to the above-discussed examples. Rather, various materials may be used to form the channel layer C1.

Referring back to FIG. 1, a source electrode S1 and a drain electrode D1 are disposed on the gate insulating layer GI1. As shown, the source electrode S1 is formed to contact a first end or outer portion of the channel layer C1, and the drain electrode D1 is formed to contact a second end or outer portion of the channel layer C1. In more detail, the source electrode S1 is formed on an upper surface of a portion of the gate insulating layer GI1, a sidewall of the channel layer C1 and an upper surface of the first end or outer portion of the channel layer C1. In this example, the first end or outer portion of the channel layer C1 covered by the source electrode S1 is a non-fluorine-containing region, which does not contain fluorine. Similarly, the drain electrode D1 is formed on an upper surface of an opposite portion of the gate insulating layer GI1, a sidewall of the channel layer C1 and an upper surface of the second end or outer portion of the channel layer C1. In this example, the second end or outer portion covered by the drain electrode D1 is also a non-fluorine-containing region, which does not contain fluorine.

The source electrode S1 and the drain electrode D1 may have a single layer structure or a multi-layer structure. And, the source electrode S1 and the drain electrode D1 may formed of the same or substantially the same material as the gate G1. Alternatively, the source electrode S1 and the drain electrode D1 may be formed of different materials than the gate G1.

Referring still to FIG. 1, the channel layer C1 includes a fluorine-containing region 10, which includes fluorine (F) in addition to the elements of the material of the channel layer C1 discussed above. The fluorine-containing region 10 is formed in an upper portion (surface portion) of the channel layer C1 between the source electrode S1 and the drain electrode D1. The portion (e.g., the upper or surface portion) of the channel layer C1 in which the fluorine-containing region 10 is formed is referred to as a back channel region. The fluorine-containing region 10 may be a plasma-treated region treated with plasma including fluorine. In one example, the thickness of the fluorine-containing region 10 may be between about 1 nm and about 40 nm, inclusive. In the example embodiment shown in FIG. 1, the depth of the fluorine-containing region 10 from the surface of the channel layer C1 may be between about 1 nm and about 40 nm, inclusive.

According to at least one example embodiment, the carrier concentration of the fluorine-containing region 10 is lower than that of other channel regions because the number of oxygen vacancies and defects are reduced in the fluorine-containing region 10 when the fluorine-containing region 10 is formed in the back channel region (e.g., the upper or surface portion in FIG. 1) of the channel layer C1. Because oxygen vacancies and defects act as carriers in an oxide layer, a reduction in the number of oxygen vacancies and defects in the upper portion (back channel region) of the channel layer C1 corresponds to a reduction in the carrier concentration thereof. Thus, variations in characteristics of the transistor due to light are reduced by forming the fluorine-containing region 10.

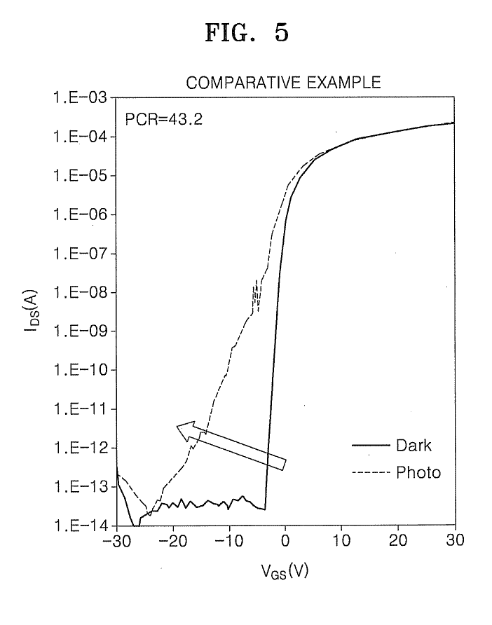

In FIG. 1, the upper portion (back channel region) of the channel layer C1 is arranged further from the gate G1 than a lower portion (front channel region) of the channel layer C1, and may affect characteristics of a sub-threshold voltage. For example, as the carrier concentration of the upper portion (back channel region) of the channel layer C1 increases, photocurrent generated from the upper portion due to light increases. As a result, a gate voltage (see, e.g., V_{GS} of FIG. 5) and drain current (see, e.g., I_{DS} of FIG. 5) characteristic graph becomes distorted relatively easily due to light. For example, in the gate voltage (see, e.g., V_{GS} of FIG. 5)-drain current (see, e.g., I_{DS} of FIG. 5) characteristic graph, a sub-threshold voltage region may be distorted relatively easily. By contrast, in at least the example embodiment shown in FIG. 1, when the fluorine-containing region 10 is formed in the upper portion (back channel region) of the channel layer C1, the number of oxygen vacancies and defects in the upper portion (back channel region) of the channel layer C1 is reduced. Thus, the carrier concentration of the upper portion (back channel region) of the channel layer C1 is reduced, and the generation of photocurrent in the upper portion (e.g., back channel region) of the channel layer C1 is suppressed. Thus, variations in characteristics of the transistor due to light are also suppressed.

In the example embodiment shown in FIG. 1, an interface region between the channel layer C1 and the source electrode S1 and an interface region between the channel layer C1 and the drain electrode D1 are regions that do not contain fluorine (non-fluorine-containing regions). If the interface region between the channel layer C1 and the source electrode S1 and the interface region between the channel region C1 and the drain electrode D1 are fluorine-containing regions, a contact resistance between the channel layer C1 and the source/drain electrode S1/D1 increases. As a result, operating characteristics of the transistor may deteriorate. However, according to at least the example embodiment shown in FIG. 1, when the interface region between the channel layer C1 and the source electrode S1 and the interface region between the channel layer C1 and the drain electrode D1 are non-fluorine-containing regions, the contact resistance between the channel layer C1 and the source/drain electrode S1/D1 are maintained at a relatively low level, which may improve operating characteristics of the transistor.

Referring back to FIG. 1, the transistor further includes a passivation layer P1 disposed on the gate insulating layer GI1 to cover the channel layer C1, the source electrode S1, and the drain electrode D1. The passivation layer P1 may be a silicon oxide layer, a silicon oxynitride layer, a silicon nitride layer, an organic layer or may have a stack structure including at least two layers of the group including the silicon oxide layer, the silicon oxynitride layer, the silicon nitride layer, and the organic layer.

FIG. 2 is a cross-sectional view of a transistor according to another example embodiment. The transistor shown in FIG. 2 is a thin film transistor (TFT) having a top gate structure in which a gate G2 is disposed above a channel layer 02.

Referring to FIG. 2, the channel layer C2 is disposed on a substrate SUB2. The channel layer C2 may be formed from an oxide semiconductor that is the same as, substantially the same as, or similar to the channel layer C1 of FIG. 1. For example, the channel layer C2 may include a ZnO-based oxide semiconductor. When the channel layer C2 includes the ZnO-based oxide semiconductor, the ZnO-based oxide semiconductor may include at least one selected from the group including: a transition metal such as hafnium (Hf), yttrium (Y), tantalum (Ta), zirconium (Zr), titanium (Ti), copper (Cu), nickel (Ni), or chromium (Cr), a Group III element such as indium (In), gallium (Ga), or aluminum (Al), a Group IV element such as tin (Sn), a Group II element such as magnesium (Mg), and other elements. However, a material for the channel layer C2 is not limited thereto, and various materials may be used to form the channel layer C2.

Still referring to FIG. 2, the channel layer C2 includes a fluorine-containing region 20 formed in a lower portion (e.g., lower surface portion) of the channel layer C2. In this example embodiment, the lower portion of the channel layer C2 serves as the back channel region of the channel layer C2. The fluorine-containing region 20 may be similar to the fluorine-containing region 10 illustrated in FIG. 1 in that the fluorine-containing region 20 may be a plasma-treated region treated with plasma including fluorine (F). The carrier concentration of the fluorine-containing region 20 may be lower than that of the remaining regions of the channel layer C2 (the front channel region). The thickness of the fluorine-containing region 20 may be between about 1 nm and about 40 nm, inclusive. Similar to the example embodiment shown in FIG. 1, the fluorine-containing region 20 reduces variations in characteristics of the transistor due to light.

The transistor shown in FIG. 2 further includes a source electrode S2 and a drain electrode D2 disposed on the substrate SUB2. The source electrode S2 is formed to contact a first end or outer portion of the channel layer C2, and the drain electrode D2 is formed to contact a second end or outer portion of the channel layer C2. In more detail, the source electrode S2 is formed on an upper surface of a portion of the substrate SUB2, a sidewall of the channel layer C2 and an upper surface of the first end or outer portion of the channel layer C2. Similarly, the drain electrode D2 is formed on an upper surface of an opposite portion of the substrate SUB2, a sidewall of the channel layer C2 and an upper surface of the second end or outer portion of the channel layer C2.

In the example embodiment shown in FIG. 2, a substantial portion (e.g., most) of an interface region between the source electrode S2 and the channel layer C2 is a non-fluorine-containing region. Similarly, a substantial portion (e.g., most) of an interface region between the drain electrode D2 and the channel layer C2 is a non-fluorine-containing region. Only a relatively small portion of the interface between the channel layer C2 and the source electrode S2 and between the channel layer 02 and the drain electrode D2 contains fluorine. Thus, similar to the example embodiment shown in FIG. 1, a contact resistance between the channel layer C2 and the source/drain electrode S2/D2 is maintained at a relatively low level.

Although, in at least this example embodiment, the source/drain electrode S2/D2 covers upper surface portions and side surface (or sidewalls) portions of the channel layer 02, the source/drain electrode S2/D2 may not cover the side surface of the channel layer C2 in alternative example embodiments. In this case, the source/drain electrode S2/D2 may not contact the fluorine-containing region 20 at all. That is, for example, the entire interface between the channel layer C2 and the source electrode S2 and between the channel layer C2 and the drain electrode D2 may be non-fluorine-containing regions.

Returning to FIG. 2, a gate insulating layer GI2 is disposed to cover the channel layer C2, the source electrode S2, and the drain electrode D2. The gate G2 is disposed on the gate insulating layer GI2. In FIG. 2, the gate G2 is disposed above the channel layer C2 and has a width less than the width of the channel layer C2 in the X-direction. However, example embodiments are not limited thereto. Rather, the gate G2 may have a width greater than or equal to the width of the channel layer C2.

A passivation layer P2 is disposed on the gate insulating layer GI2 to cover the gate G2.

Materials and thicknesses of the substrate SUB2, the source electrode S2, the drain electrode D2, the gate insulating layer GI2, the gate G2, and the passivation layer P2 of FIG. 2 may be the same as or similar to those of the substrate SUB1, the source electrode S1, the drain electrode D1, the gate insulating layer GI1, the gate G1, and the passivation layer P1 of FIG. 1.

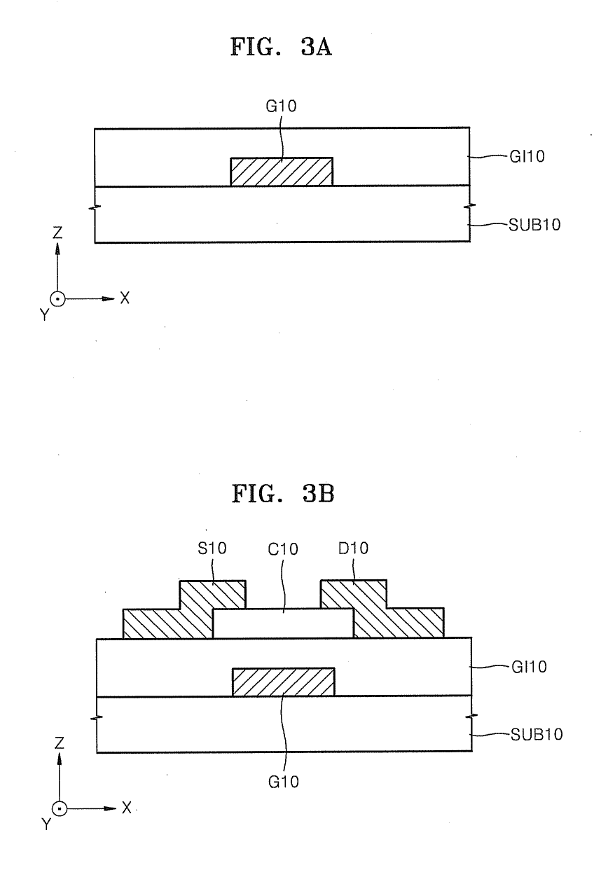

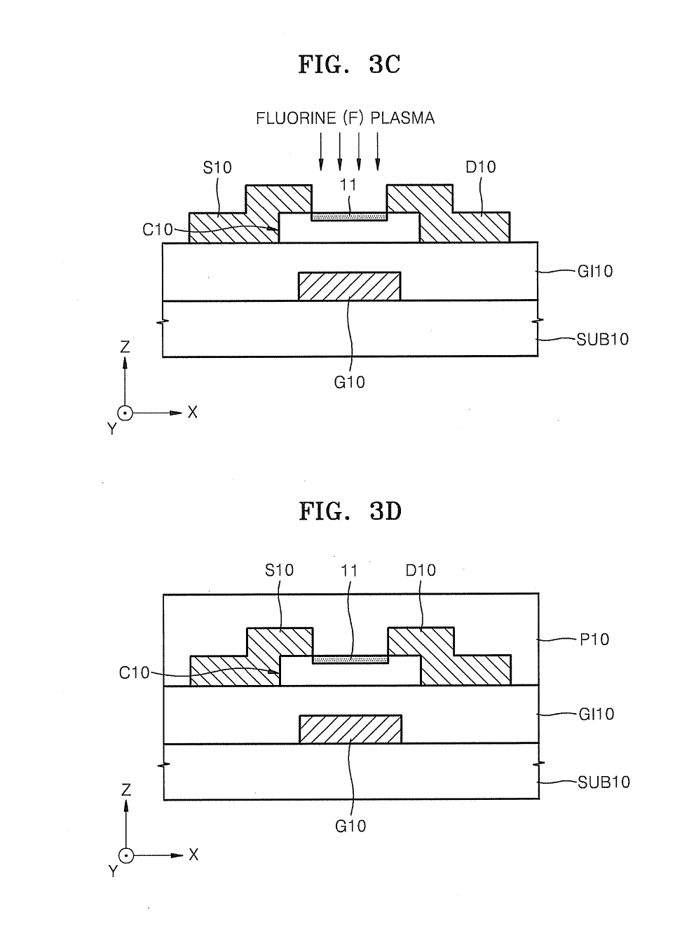

FIGS. 3A through 3D are cross-sectional views illustrating a method of manufacturing a transistor according to an example embodiment. In this example embodiment, a TFT having a bottom gate structure is manufactured.

Referring to FIG. 3A, a gate G10 is formed on a substrate SUB10, and a gate insulating layer GI10 is formed on the substrate SUB10 to cover the gate G10. The substrate SUB10 may be a glass substrate, a plastic substrate, a silicon substrate, or any other substrate used in conventional semiconductor devices. The gate G10 may be formed of an electrode material such as a metal, a conductive oxide, or the like. The gate insulating layer GI10 may be formed of a silicon oxide, a silicon oxynitride, a silicon nitride, or another material such as a high-k dielectric material having a dielectric constant higher than the silicon nitride. The gate insulating layer GI10 may have a multi-layer structure including at least two layers selected from the group including a silicon oxide layer, a silicon oxynitride layer, a silicon nitride layer, and a high-k dielectric material layer. When the gate insulating layer GI10 has a multi-layer structure, the gate insulating layer GI10 may include the silicon nitride layer and the silicon oxide layer, which are sequentially stacked on substrate SUB10 and the gate G10.

Referring to FIG. 3B, a channel layer C10 is formed on the gate insulating layer GI10 above the gate G10. In FIG. 3B, the width of the channel layer C10 in the X-axis direction is greater than the width of the gate G10 in the X-axis direction. However, the width of the channel layer C10 may be less than or equal to the width of the gate G10 in alternative example embodiments. The channel layer C10 may be formed using, for example, a physical vapor deposition (PVD) method, such as sputtering or evaporation. However, the channel layer C10 may also be formed using other methods, such as chemical vapor deposition (CVD) or atomic layer deposition (ALD).

The channel layer C10 may include an oxide semiconductor, for example, a ZnO-based oxide semiconductor. When the channel layer C10 includes a ZnO-based oxide semiconductor, the ZnO-based oxide semiconductor may include at least one selected from the group including: a transition metal such as hafnium (Hf), yttrium (Y), tantalum (Ta), zirconium (Zr), titanium (Ti), copper (Cu), nickel (Ni), or chromium (Cr), a Group III element such as indium (In), gallium (Ga), or aluminum (Al), a Group IV element such as tin (Sn), a Group II element such as magnesium (Mg), and other elements. In more detail, for example, the channel layer C10 may include: hafnium-indium-zinc-oxide (HfInZnO), gallium-indium-zinc-oxide (GaInZnO), yttrium-indium-zinc-oxide (YInZnO), tantalum-indium-zinc-oxide (TaInZnO), or the like. The oxide semiconductor used to form the channel layer C10 may be amorphous or crystalline, or a mixture of amorphous and crystalline. A material for the channel layer C10 is not limited thereto. Rather, various materials may be used to form the channel layer C10.

Still referring to FIG. 3B, a source electrode S10 and a drain electrode D10 are formed on the gate insulating layer GI10. The source electrode S10 is formed to contact a first end or outer portion of the channel layer C10 and the drain electrode D10 is formed to contact a second end or outer portion of the channel layer C10. In more detail, the source electrode S10 is formed on an upper surface of a portion of the gate insulating layer GI10, a sidewall of the channel layer C10 and an upper surface of the first end or outer portion of the channel layer C10. Similarly, the drain electrode D10 is formed on an upper surface of an opposite portion of the gate insulating layer GI10, a sidewall of the channel layer C10 and an upper surface of the second end or outer portion of the channel layer C10.

The source electrode S10 and the drain electrode D10 may have a single layer or multi-layer structure. The source electrode S10 and the drain electrode D10 may be formed of the same or substantially the same material as the gate G10. Alternatively, the source electrode S10 and the drain electrode D10 may be formed of other materials.

Referring to FIG. 3C, an exposed portion of the channel layer C10 between the source electrode S10 and the drain electrode D10 is treated with plasma including fluorine (F). As a result, a fluorine-containing region 11 is formed in an upper portion (back channel region) of the channel layer C10 between the source electrode S10 and the drain electrode D10. At least one selected from the group including: F₂, NF₃, SF₆, CF₄, C₂F₆, CHF₃, CH₃F, and CH₂F₂ may be used as a source of fluorine (F) when performing the plasma treating. Also, an inert gas such as argon (Ar), helium (He), or xenon (Xe) may be used as a carrier gas when performing the plasma treating. The plasma treating may be performed using, for example, reactive ion etching (RIE) equipment, plasma-enhanced chemical vapor deposition (PECVD) equipment, inductively coupled plasma-chemical vapor deposition (ICP-CVD) equipment, or the like. When performing the plasma treating using the RIE equipment, a source power of between about 100 W and about 1,000 W, inclusive, may be used in a temperature range between about 20° C. and about 250° C., inclusive, and a pressure range of between about 10 mTorr and about 1,000 mTorr, inclusive. In this example, the flow rate of the source gas of fluorine (F) may be between about 10 sccm and about 100 sccm, inclusive, and the flow rate of the carrier gas may be between about 1 sccm and about 50 sccm, inclusive. However, the above-discussed process conditions for the plasma treatment are illustrative and may be changed as necessary. The fluorine-containing region 11 formed using the process may be regarded as a fluorine-doped region. The fluorine element may be doped into the channel layer C10 at a depth of between about 1 nm and about 40 nm, inclusive. In more detail, the thickness of the fluorine-containing region 11 may be between about 1 nm and about 40 nm, inclusive. However, the thickness range is illustrative and may be changed as necessary.

Referring to FIG. 3D, a passivation layer P10 is formed on the gate insulating layer GI10 to cover the channel layer C10 including the fluorine-containing region 11, the source electrode S10 and the drain electrode D10. The passivation layer P10 may be a silicon oxide layer, a silicon oxynitride layer, a silicon nitride layer, an organic layer or may have a stack structure in which, at least two layers of the group including the silicon oxide layer, the silicon oxynitride layer, the silicon nitride layer, and the organic layer are stacked. The transistor formed using the above-described method may be annealed at a given, desired or predetermined temperature.

According to at least some example embodiments, when the upper portion (back channel region) of the channel layer C10 between the source electrode S10 and the drain electrode D10 is treated with fluorine-containing plasma, the number of oxygen vacancies and defects in the upper portion (back channel region) of the channel layer C10 is reduced, and thus, the carrier concentration of the upper portion (back channel region) of the channel layer C10 is reduced. Accordingly, the occurrence of photocurrent in the upper surface (back channel region) of the channel layer C10 is suppressed, and variations in characteristics of the transistor due to light are also suppressed.

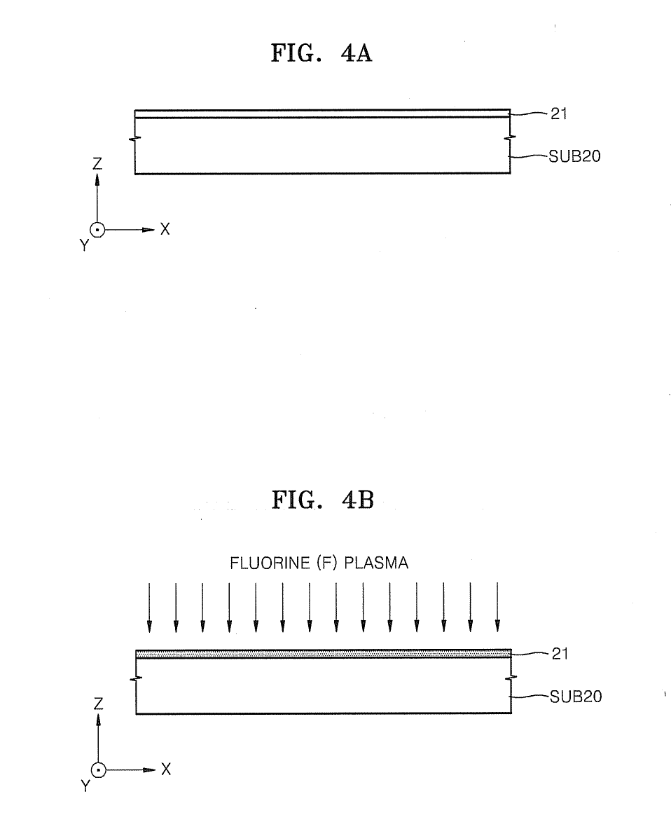

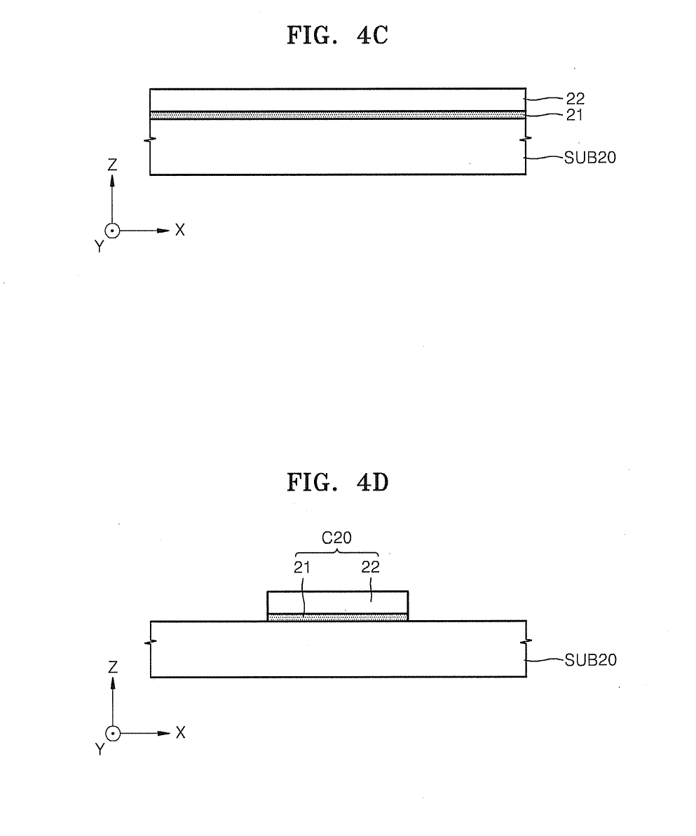

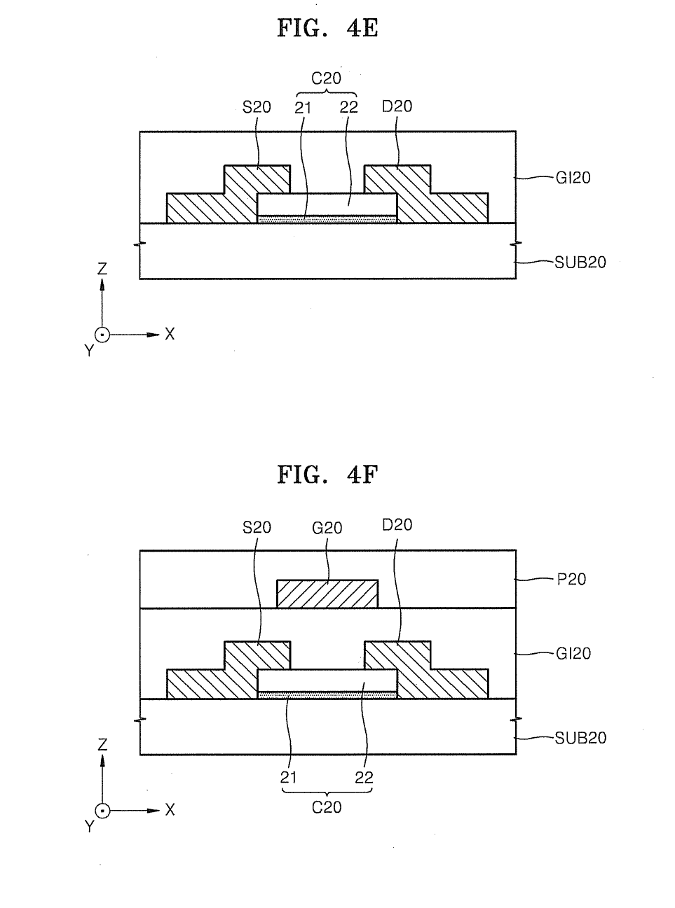

FIGS. 4A through 4F are cross-sectional views illustrating a method of manufacturing a transistor according to another example embodiment. In the example embodiment shown in FIGS. 4A through 4F, a TFT having a top gate structure is manufactured.

Referring to FIG. 4A, a first channel material layer 21 is formed on a substrate SUB20. The first channel material layer 21 may be formed of material that is the same as, or similar to, that of the channel layer C10 discussed above with regard to FIG. 3B. However, the first channel material layer 21 may be formed to have a relatively small thickness of between about 1 nm and about 40 nm, inclusive.

Referring to FIG. 4B, the first channel material layer 21 is treated with plasma including fluorine (F). As a result, the first channel material layer 21 becomes a fluorine-containing region. Because the first channel material layer 21 has a relatively small thickness of between about 1 nm and about 40 nm, inclusive, the entire first channel material layer 21 includes fluorine, and thus, is a fluorine-containing region. The first channel material layer 21 including fluorine is referred to as a “fluorine-containing first channel material layer 21.” The plasma treating described with regard to this example embodiment may be the same as or similar to the plasma treating described with reference to FIG. 3C. Thus, a detailed description is not repeated.

Referring to FIG. 4C, a second channel material layer 22 is formed on the fluorine-containing first channel material layer 21. The second channel material layer 22 may be formed of an oxide that is the same as or from the same group as the first channel material layer 21 discussed above with regard to FIG. 4A before the first channel material layer 21 is plasma treated. However, in alternative example embodiments, the second channel material layer 22 may be formed of an oxide from a different group than the first channel material layer 21 of FIG. 4A.

Referring to FIG. 4D, the second channel material layer 22 and the fluorine-containing first channel material layer 21 are patterned to form a channel layer C20. The channel layer C20 may correspond to the channel layer C2 discussed above with regard to FIG. 2. The fluorine-containing first channel material layer 21 disposed in a lower portion (back channel region) of the channel layer C20 corresponds to the fluorine-containing region 20 shown in FIG. 2.

Referring to FIG. 4E, a source electrode S20 and a drain electrode D20 are formed on the substrate SUB20. The source electrode S20 is formed to contact a first end or outer portion of the channel layer C20, and the drain electrode D20 is formed to contact a second end or outer portion of the channel layer C20. In more detail, the source electrode S20 is formed on an upper surface of a portion of the substrate SUB20, a sidewall of the channel layer C20 and an upper surface of the first end or outer portion of the channel layer C20. Similarly, the drain electrode D20 is formed on an upper surface of an opposite portion of the substrate SUB20, a sidewall of the channel layer C20 and an upper surface of the second end or outer portion of the channel layer C20.

A gate insulating layer GI20 is formed on the substrate SUB20 to cover the channel layer C20, the source electrode S20, and the drain electrode D20. The gate insulating layer GI20 may be formed of material that is the same as, or similar to, the above-discussed gate insulating layer GI10 or may have the same stack structure as the above-discussed gate insulating layer GI10. Alternatively, the gate insulating layer GI20 may have a reverse structure relative to the above-discussed gate insulating layer GI10.

Referring to FIG. 4F, a gate G20 is formed on the gate insulating layer GI20 above the channel layer C20. In this example embodiment, the gate G20 has a width less than the width of the channel layer C20 in the X-direction. Alternatively, however, the width of the gate G20 may be greater than or equal to the width of the channel layer C20.

A passivation layer P20 is formed on the gate insulating layer GI20 to cover the gate G20. The passivation layer P20 may be formed of material that is the same as, or similar to, the passivation layer P10 of FIG. 3D or may have a stack structure that is the same as, or similar to, the passivation layer P10 of FIG. 3D. The transistor formed using the above-described method may be annealed at a given, desired or predetermined temperature.

FIG. 5 is a graph showing example variations in gate voltage V_{GS} and drain current I_{DS} characteristics in response to irradiated light for a transistor according to a comparative example. The transistor used to obtain the result of FIG. 5 corresponds to the case where the entire channel layer C1 of FIG. 1 is a non-fluorine-containing region and does not include a fluorine-containing region 10. In other words, the transistor according to the comparative example uses a channel layer that is not treated with, and does not contain, fluorine. The material of the channel layer of the transistor according to the comparative example is HfInZnO and the thickness of the channel layer is about 50 nm. In FIG. 5, ‘Dark’ indicates a case where light is not irradiated on the transistor, and ‘Photo’ indicates a case where light of about 20,000 nits is irradiated onto the transistor.

As shown in FIG. 5, the graph shifts to the left in response to the irradiated light. In more detail, a lower portion of the graph (a sub-threshold voltage region) shifts substantially to the left in response to the irradiated light. Accordingly, characteristics of the transistor vary relatively easily and substantially in response to the irradiated light when the channel layer is not treated with fluorine. An upper portion (back channel region) of the channel layer of the transistor according to the comparative example is a region positioned farther from a gate than a lower portion (front channel region) of the channel layer, and may affect characteristics of a sub-threshold voltage. As the carrier concentration of the upper portion (back channel region) of the channel layer increases, photocurrent generated therefrom due to light also increases. Consequently, a gate voltage V_{GS}-drain current I_{DS} characteristic graph becomes distorted more easily in response to irradiated light. For example, in the gate voltage V_{GS}-drain current I_{DS} characteristic graph, a sub-threshold voltage region is distorted relatively easily. For this reason, as in FIG. 5, the gate voltage V_{GS}-drain current I_{DS} characteristic graph becomes distorted in response to irradiated light.

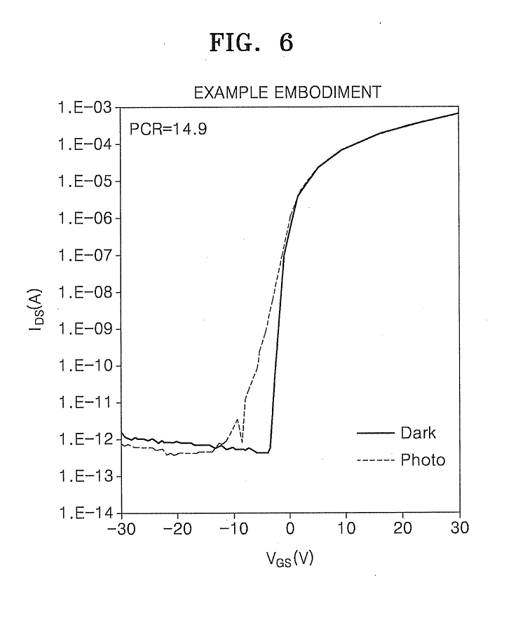

FIG. 6 is a graph showing example variations in gate voltage V_{GS}-drain current I_{DS} characteristics of a transistor in response to irradiated light according to an example embodiment. The transistor used to obtain the results shown in FIG. 6 has the structure of FIG. 1. In this regard, the channel layer C1 is formed of HfInZnO, and the thickness of the channel layer C1 is about 50 nm. The fluorine-containing region 10 is a region treated with fluorine-containing plasma using RIE equipment. In this regard, CHF₃ and Ar were used as a source gas of fluorine (F) and a carrier gas, respectively, and a source power, a process pressure, and a process temperature are about 300 W, about 50 mTorr, and about 25° C., respectively. The conditions of the irradiated light are the same as that discussed above with regard to FIG. 5.

Referring to FIG. 6, although the graph is shifted slightly to the left in response to the irradiated light, the degree of variation is substantially less than that shown in FIG. 5. A photocurrent ratio (PCR) corresponding to an integral area ratio of the graph in the case where light is irradiated onto the transistor (Photo) and the graph in the case where light is not irradiated onto the transistor (Dark) is about 14.9, which is about ⅓ of PCR of FIG. 5, which is about 43.2. Accordingly, when the fluorine-containing region 10 is formed in the back channel region of the channel layer, variations in characteristics of the transistor due to light are suppressed (e.g., effectively suppressed and/or minimized).

As described above, according to at least some example embodiments, a transistor having a higher photo reliability (e.g., light reliability) and/or improved performance (e.g., relatively high mobility or the like) may be manufactured more easily.

Transistors according to at least some example embodiments may be used as switching devices and/or driving devices in flat panel display devices such as liquid crystal display devices, organic light-emitting display devices and the like. As described above, transistors according to at least some example embodiments may have reduced characteristic variations due to light and/or improved performance. Accordingly, the reliability and/or performance of flat panel display devices including these transistors may be improved. For example, at least some example embodiments may suppress and/or prevent image variations due to light. The structures of liquid crystal display (LCD) devices and organic light-emitting display (OLED) devices are well known, and thus, detailed descriptions thereof will be omitted. Transistors according to at least some example embodiments may be used for various purposes in other electronic devices such as memory devices and logic devices, as well as flat panel display devices (either flexible or non-flexible).

It should be understood that the example embodiments described herein should be considered in a descriptive sense only and not for purposes of limitation. For example, it will be understood by one of ordinary skill in the art that the components and the structures of the transistors illustrated in FIGS. 1 and 2 may be modified and changed. In more detail, for example, in the transistors of FIGS. 1 and 2, regions (e.g., front channel region) other than the fluorine-containing regions 10 and 20 of the channel layers C1 and C2 may have a multi-layer structure. Also, the method of FIGS. 3A through 3D and the method of FIGS. 4A through 4F may be changed in various ways. As an example, a method of forming the fluorine-containing regions 10, 11, 20, and 21 is not limited to plasma treating and may be changed. Furthermore, it will be understood by one of ordinary skill in the art that example embodiments may be applied to various transistors as well as oxide thin film transistors (TFTs). Descriptions of features or aspects within each example embodiment should typically be considered as available for other similar features or aspects in other example embodiments.

What is claimed is:

1. A transistor comprising:
a gate;
a channel layer disposed above the gate and including an oxide semiconductor;
a source electrode contacting a first end portion of the channel layer; and
a drain electrode contacting a second end portion of the channel layer; wherein
the channel layer further includes a fluorine-containing region formed in an upper portion of the channel layer between the source electrode and the drain electrode.

2. The transistor of claim 1, wherein only the upper portion of the channel layer between the source electrode and the drain electrode contains fluorine.

3. The transistor of claim 1, wherein an interface region between the channel layer and at least one of the source electrode and the drain electrode is a non-fluorine-containing region.

4. The transistor of claim 1, wherein the fluorine-containing region is a region treated with plasma including fluorine.

5. The transistor of claim 1, wherein the fluorine-containing region has a thickness of between about 1 nm and about 40 nm, inclusive.

6. The transistor of claim 1, wherein the oxide semiconductor is a ZnO-based oxide semiconductor.

7. The transistor of claim 6, wherein the ZnO-based oxide semiconductor includes at least one of hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

8. The transistor of claim 1, wherein the fluorine-containing region is formed in a back channel region of the channel layer.

9. A flat panel display device comprising the transistor of claim 1.

10. A transistor comprising:
a channel layer including an oxide semiconductor and a fluorine-containing region formed in a lower portion of the channel layer;
a source electrode contacting a first end portion of the channel layer;
a drain electrode contacting a second end portion of the channel layer; and
a gate disposed above the channel layer.

11. The transistor of claim 10, wherein only the lower portion of the channel layer contains fluorine.

12. The transistor of claim 10, wherein the source electrode covers an upper surface of the first end portion of the channel layer, and the drain electrode covers an upper surface of the second end portion of the channel layer.

13. The transistor of claim 10, wherein the fluorine-containing region is a region treated with plasma including fluorine.

14. The transistor of claim 10, wherein the fluorine-containing region has a thickness of between about 1 nm and about 40 nm, inclusive.

15. The transistor of claim 10, wherein the oxide semiconductor is a ZnO-based oxide semiconductor.

16. The transistor of claim 15, wherein the ZnO-based oxide semiconductor includes at least one of hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

17. The transistor of claim 10, wherein the fluorine-containing region is formed across an entire width of the lower portion of the channel layer.

18. The transistor of claim 10, wherein the channel layer has a multi-layer structure.

19. A flat panel display device comprising the transistor of claim 10.

20. A method of manufacturing a transistor, the method comprising:
forming a gate;
forming a gate insulating layer to cover the gate;
forming a channel layer on the gate insulating layer, the channel layer including an oxide semiconductor;
forming a source electrode and a drain electrode, the source electrode contacting a first end portion of the channel layer and the drain electrode contacting a second end portion of the channel layer; and
forming a fluorine-containing region in an upper portion of the channel layer between the source electrode and the drain electrode.

21. The method of claim 20, wherein only the upper portion of the channel layer between the source electrode and the drain electrode is a fluorine-containing region.

22. The method of claim 20, wherein the forming of the fluorine-containing region comprises:
treating the upper portion of the channel layer between the source electrode and the drain electrode with plasma including fluorine.

23. The method of claim 22, wherein the treating the upper portion with plasma uses a source gas including at least one of F₂, NF₃, SF₆, CF₄, C₂F₆, CHF₃, CH₃F, and CH₂F₂.

24. The method of claim 22, wherein the treating the upper portion with plasma is performed using one of reactive ion etching (RIE) equipment, plasma-enhanced chemical vapor deposition (PECVD) equipment, and inductively coupled plasma-chemical vapor deposition (ICP-CVD) equipment.

25. The method of claim 20, wherein the fluorine-containing region is formed to have a thickness of between about 1 nm and about 40 nm, inclusive.

26. The method of claim 20, wherein the oxide semiconductor is a ZnO-based oxide semiconductor.

27. The method of claim 26, wherein the ZnO-based oxide semiconductor includes at least one of hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).

28. A method of manufacturing a transistor, the method comprising:
forming a channel layer including an oxide semiconductor and having a fluorine-containing region in a lower portion of the channel layer;
forming a source electrode and a drain electrode, the source electrode contacting a first end portion of the channel layer, and the drain electrode contacting a second end portion of the channel layer;
forming a gate insulating layer to cover the channel layer, the source electrode, and the drain electrode; and
forming a gate on the gate insulating layer.

29. The method of claim 28, wherein only the lower portion of the channel layer includes fluorine.

30. The method of claim 28, wherein the fluorine-containing region is formed across an entire width of the lower portion of the channel layer.

31. The method of claim 28, wherein the forming of the channel layer comprises:
forming a first channel material layer;
treating the first channel material layer with plasma including fluorine; and
forming a second channel material layer on the first channel material layer.

32. The method of claim 31, wherein the treating the first channel material layer with plasma uses a source gas including at least one of F₂, NF₃, SF₆, CF₄, C₂F₆, CHF₃, CH₃F, and CH₂F₂.

33. The method of claim 31, wherein the treating the first channel material layer with plasma is performed using one of reactive ion etching (RIE) equipment, plasma-enhanced chemical vapor deposition (PECVD) equipment, and inductively coupled plasma-chemical vapor deposition (ICP-CVD) equipment.

34. The method of claim 28, wherein the fluorine-containing region has a thickness of between about 1 nm and about 40 nm, inclusive.

35. The method of claim 28, wherein oxide semiconductor is a ZnO-based oxide semiconductor.

36. The method of claim 35, wherein the ZnO-based oxide semiconductor includes at least one of hafnium (Hf), yttrium (Y), tantalum (Ta), zirconium (Zr), titanium (Ti), copper (Cu), nickel (Ni), chromium (Cr), indium (In), gallium (Ga), aluminum (Al), tin (Sn), and magnesium (Mg).
